(19) United States
(12) Patent Application Publication
(10) Pub. No.: US 2004/0130005 A1
(43) Pub. Date: Jul. 8, 2004

(54) Underlayer for polysilicon TFT

(76) Inventors: Guillaume Guzman, Veneux-les-Sablons (FR); Sonia Mechken, Paris (FR)

Correspondence Address: CORNING INCORPORATED, SP-TI-3-1, CORNING, NY, 14831

(21) Appl. No.: 10/668,873

(22) Filed: Sep. 23, 2003

(30) Foreign Application Priority Data
Sep. 25, 2002 (EP) 02 292 358.5

(51) Int. Cl. H01L 23/58

(52) U.S. Cl. 257/636

(57) ABSTRACT

Polycrystalline silicon in semiconductor device is usually crystallized at high temperature annealing. Generally a low heat conducting underlayer is needed to protect substrate and silicon from high temperature crystallization. This invention proposes a new underlayer that improves silicon crystallization and protects substrate during the annealing process. The semiconductor device is a thin film transistor suitable for use in such applications as liquid crystal displays, light emitting diodes, imaging sensors and photovoltaic cells.

### RELATED APPLICATION

This application claims the benefit of priority from European Patent Application No. 02 292 358.5, filed, Sep. 25, 2002, the content of which is incorporated herein by reference.

### BACKGROUND OF THE INVENTION

1. Field of the Invention

The invention relates generally to photovoltaic components, imaging sensors and active matrix liquid crystal displays (AMLCDs), particularly active matrix organic light emitting devices (AMOLEDs or active matrix OLEDs). More particularly, the invention relates to the use of polycrystalline silicon in AMOLED thin film transistors (TFTs) and also in AMLCD TFTs.

2. Technical Background

Liquid crystal displays (LCDs) are flat panel displays which depend upon external sources of light for illumination. They are manufactured as segmented displays or in one of two basic configurations. The substrate needs (other than being transparent and capable of withstanding the chemical conditions to which it is exposed during display processing) of the two matrix types vary. The first type is intrinsic matrix addressed, relying upon the threshold properties of the liquid crystal material. The second is extrinsic matrix or active matrix (AM) addressed, in which an array of diodes, metal-insulator-metal (MIM) devices, or thin film transistors (TFTs) supplies an electronic switch to each pixel. In both cases, two sheets of glass form the structure of the display. The separation between the two sheets is the critical gap dimension, of the order of 5-10 μm.

An active matrix liquid crystal display is a flat panel display in which the display medium is liquid crystal and each picture element (pixel) is driven by an active device: a thin film transistor (TFT). Active matrix OLEDs are flat panel displays in which the display medium is an organic electroluminescent material and each picture element (pixel) is equally driven by a thin film transistor (TFT).

Currently, flat panel AMLCDs are predominantly manufactured using a-Si: H TFTs for the pixel switching device. However, this technology cannot be used for AMOLED TFTs. Indeed, a-Si: H TFTs cannot provide the electrical current necessary to drive AMOLED TFTs because of the very low mobility (0.001 cm²/Vs for holes, 0.5 to 1 cm²/Vs for the electrons) of the semiconductor material. Moreover, the metastability of the semiconductor material can lead to rapid degradation of the device. It has been recognised that polycrystalline silicon (polysilicon or poly-Si) TFT technology is the solution for AMOLED TFTs because the mobility exceeds the mobility of amorphous silicon (a-Si) TFTs by two orders of magnitude and also because the material is intrinsically stable.

It is also recognized that next generation flat panel AMLCDs, require use of polysilicon TFTs instead of a-Si: H TFTs to allow integration of external electronics on the glass. It is expected that this will result in a more reliable and lower cost display. Achieving this will require the formation of polycrystalline silicon films on LCD substrates. To accomplish this, most technologies today employ laser annealing methods. Indeed, using a short wavelength (248 nm, 308 nm) a short pulse laser (typically 30 ns) it is possible to melt and very rapidly re-crystallize a thin film (20-80 nm) of amorphous silicon, in the order of nanoseconds. Using laser technology, the polycrystalline silicon film can be formed with almost no thermal damage to the underlying glass substrate. The glass substrate is usually protected with a silicon dioxide or a silicon nitride under layer deposited by PECVD before silicon deposition essentially to prevent impurity migration from the glass substrate to the molten silicon film during laser annealing. The prior art process is demonstrated in FIGS. 1, 2a and 2b. FIG. 1 demonstrates the prior art method employed for the creation of the polysilicon layer. The substrate glass 12 is PECVD coated with silica 22, for example, and a layer of amorphous silicon 24 is then deposited on top of the silica underlayer 22. The silicon is melted and very rapidly recrystallized by laser annealing, represented schematically by the large arrow 28 in FIG. 1, thereby creating the polysilicon layer 24 in FIG. 2a. The heat generated from the laser light flows both laterally through the silicon film 26 as well as into the silica underlayer 22, as demonstrated by the arrows in FIG. 1. One of the disadvantages of such underlayers is that they create fixed charges at the interface between the underlayer and the polycrystalline silicon. This affects significantly electrical properties of TFTs particularly threshold voltage. For practical use of polysilicon TFT AMLCDS and AMOLEDS, both the high uniformity and reproducibility of Vₜₕ (threshold voltage) are required. FIG. 2b is a SEM photograph of the surface polysilicon surface created by this prior art method.

One of the difficulties in advancing the above laser technology is that laser light energy is limited in its amount and very expensive. For instance, at the present time industrial lasers (lambda steel lasers) are limited to 1 joule at 300 Hz. This issue is particularly problematic for large area substrates. To maintain the same laser fluence (laser energy per unit area) necessary to crystallise a larger area, the laser has to be able to deliver higher energy.

In addition, in order to enable high integration with polysilicon films on LCD substrates, silicon mobility has to be increased. Generally, silicon mobility depends on silicon grain size. To enlarge grain size, solidification velocity has to be reduced. In order to do this, thermal energy flow from the molten silicon film into the cool substrate must be suppressed. Especially for AMOLED TFTs, uniformity of the silicon crystallites has to be improved.

Various techniques have been proposed for overcoming the above needs with varying degrees of success. For example, it has been suggested to heat the glass substrate. However, this is limited to 400° C. A double pulse laser method has also been tried as well as using a dual beam where both sides of the substrate are irradiated by excimer laser light beams. In the field of energy generation from solar cells, porous silica under layers have been proposed to reduce heat diffusion during silicon crystallization in an excimer laser process.

There continues to be a need in the industry for new and improved methods for forming polycrystalline silicon films on glass substrates for use in semiconductor devices.

### SUMMARY OF THE INVENTION

One aspect of the invention is new coating material for semiconductor substrates and process for forming such coating on the substrate material. In another aspect, the present invention describes a coating which improves polysilicon properties and reduces cost of the annealing process.

In a further aspect, the invention relates a semiconductor device which, in its most basic form is made up of (1) a substrate suitable for use as an electronic or integrated circuit and (2) a layer of polycrystalline silicon in which the substrate and the silicon are separated by (3) a layer of refractory polycrystalline material, preferably a layer of porous refractory polycrystalline material.

Additional features and advantages of the invention will be set forth in the detailed description which follows, and in part will be readily apparent to those skilled in the art from that description or recognized by practicing the invention as described herein, including the detailed description which follows, the claims, as well as the appended drawings.

It is to be understood that both the foregoing general description and the following detailed description present embodiments of the invention, and are intended to provide an overview or framework for understanding the nature and character of the invention as it is claimed. The accompanying drawings are included to provide a further understanding of the invention, and are incorporated into and constitute a part of this specification. The drawings illustrate various embodiments of the invention, and together with the description serve to explain the principles and operations of the invention.

### BRIEF DESCRIPTION OF THE DRAWINGS

FIG. 1 is a cross-sectional representation of the prior art method for imparting a layer of polysilicon onto a substrate. The arrows directionally indicate heat flow during the annealing process.

FIG. 2a is a cross-sectional representation of the typical layered structure of the prior art semiconductor device.

FIG. 2b is a SEM photograph of polysilicon surface formed by utilizing the prior art crystallization of silicon after one shot KrF laser 20 ns pulse duration at 200 mj/cm2. Conventional PECVD silica is indicated as the underlayer.

FIG. 3 is a cross-sectional representation of the method of creating the layer structure of the present invention. Arrows illustrate heat flow during the annealing process.

FIG. 4 is a cross-sectional representation of the layered structure of the present invention.

FIG. 5 is a SEM photograph of surface polysilicon deposited on the refractory material (zirconia) after one shot KrF laser with 20 ns pulse duration at 200 mJ/cm².

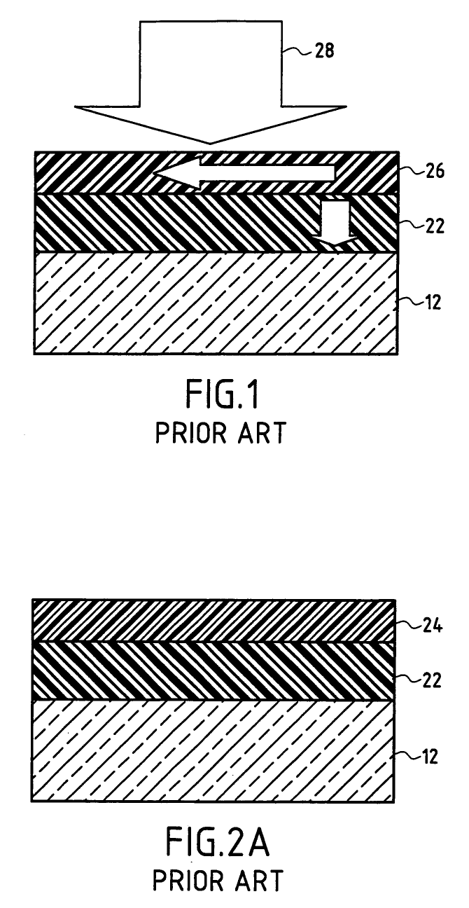

### DETAILED DESCRIPTION OF THE PREFERRED EMBODIMENTS

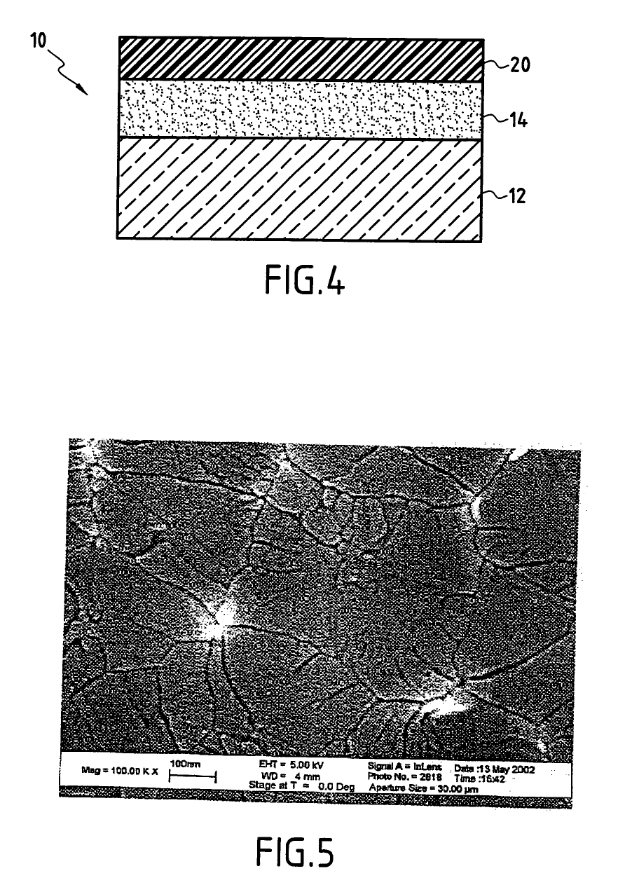

Reference will now be made in detail to the present preferred embodiment of the invention, an example of which is illustrated below and in the accompanying drawings. Whenever possible, the same reference numerals will be used throughout the drawings to refer to the same or like parts. One embodiment of the coated glass of the present invention is shown in FIG. 4, and is designated generally by the reference numeral 10.

In accordance with the invention, the coated substrate is made by coating any substrate material suitable for use in electronic and integrated circuits with a refractory polycrystalline material having low thermal conductivity, and preferably porous.

In the process contemplated by the invention and as illustrated in FIG. 3, a precursor chemical solution of the polycrystalline material is prepared in any compatible solvent followed by addition of an organic template to form a solution. A coating of the solution is deposited onto a clean glass substrate 12 using any appropriate coating method and heated to obtain a porous layer 14. What coating method is employed will depend on such considerations as the desired coating thickness for example. Amorphous silicon 16 (e.g., silane and helium) is deposited on the coated substrate to a film thickness of about 50 nm and then heat treated in an inert atmosphere, for example, under a nitrogen atmosphere to eliminate residual hydrogen. The resulting amorphous silicon-coated glass is then irradiated with excimer laser, represented by a large arrow 18 in FIG. 3, to crystallize the silicon and thereby form a polycrystalline silicon-coated glass substrate, essentially a semiconductor device (as demonstrated in FIG. 4). Between the substrate 12 and the polysilicon top layer 20, is the polycrystalline refractory material 14. The range of laser fluence which can be used for this process will vary depending on the particular laser source. In experiments performed in support of this invention, a KrF laser was used and for a thickness of 50 nm of silicon film the laser fluences ranged from 90 mj/cm²-300 mj/cm². The range of laser fluence can go up to 600 mj/cm² if a SOPRA laser is used. It is important that appropriate laser sources and fluence be used in order to crystallize the silicon and form a polysilicon coated substrate.

Coating thickness is higher than 50 nm preferably higher than 200 nm.

The polycrystalline refractory material 14 can be deposited by any of the known coating technologies in the art. For example, by wet chemistry such as sol-gel deposition, anodic oxidation or by physical and chemical deposition methods.

In a preferred embodiment, a thin film of amorphous silicon (50-80 nm) is deposited on a polycrystalline refractory coated LCD glass substrate for example, by PECVD (plasma enhanced chemical vapor deposition from a reactant gas mixture of SiH4 and He or hydrogen). The coated glass is annealed for 1 h at 450° C. under nitrogen atmosphere. Then, the silicon film is irradiated with an excimer laser (248 nm or 308 nm). As indicated in FIG. 3, it is believed that the heat from the laser 18 is absorbed and transferred laterally through the amorphous silicon layer 16 as well as downwardly into the polycrystalline refractory layer 14 (heat transfer is indicated by arrows in FIG. 3). During the annealing process, it is believed that crystallization is further induced by heat radiating back from the refractory material 14 to the silicon layer 16. The result, which is illustrated by the SEM micrograph of FIG. 5, shows good quality polycrystalline silicon having homogeneous silicon grains. The average grain size of the silicon can be increased with multiple laser shots.

In a preferred embodiment, the resulting semiconductor device 10, that is the polycrystalline silicon-coated substrate, is a thin film transistor (TFT) suitable for such uses as liquid crystal displays (LCDs), light emitting diode (LEDs) or a photovoltaic device to name a few.

Useful materials for the substrate 12 include, glass, glass-ceramics, ceramics, metal, plastic or composites of these materials. For LCD applications, we have found that glasses having certain properties are preferred. Active matrix LCDs can be classified into two categories depending upon the nature of the electrical switch located at each optical element or subpixel. Two of the most popular types of active matrix-addressed LCDs are those based on either amorphous (a-Si) or polycrystalline (p-Si) silicon thin film transistors (TFTs). Desirably, substrates for extrinsically addressed LCDs should be essentially free of alkali metal oxides to avoid the possibility of alkali metal contamination of the TFT. In addition, such substrates must be sufficiently chemically durable to withstand the reagents used during the manufacture of the TFT. It is also desirable that the expansion mismatch between the glass and the silicon present in the TFT array be maintained at a relatively low level even as processing temperatures for the substrates increase. The need for low thermal expansion mismatch is particularly desirable for “chip-on-glass” technology (COG) in which, as the name implies, the silicon chips are mounted directly on the glass substrate. Therefore, glasses useful for the present LCD devices are those in which the coefficient of thermal expansion closely match that of silicon, that is, linear expansion of between about 32-46×10⁻⁷/° C., most preferably 32-40×10⁻⁷/° C. in the temperature range of 25°-300° C.

Recent improvements in the resolution of extrinsically addressed LCDs have led to the development of another requirement for the glass substrate, namely, high glass strain point which is an indication of the thermal shrinkage of the glass. The lower the strain point, the greater is this thermal shrinkage. Low thermal shrinkage is desirable for precise alignment during successive photolithographic and other patterning steps during the TFT processing. Consequently, glasses having higher strain points are generally preferred for extrinsically addressed LCDs, particularly those which employ polysilicon TFT technology. Thus, there has been considerable research to develop glasses demonstrating high strain points so that thermal shrinkage is minimized during device processing. Corning Code 1737 glass (available from Corning Incorporated, Corning, N.Y.), which has one of the highest strain points, if not the highest (666° C.) in the AMLCD substrate industry and is rapidly becoming an industry standard is a preferred glass substrate for the present LCD devices.

Most preferably, in addition to the above desirable properties useful glass substrates are those that are free of arsenic and other environmentally harmful components. Another particularly preferred substrate is a glass which is available from Corning Incorporated under the product name, EAGLE2000.

One particularly useful glass composition for the present LCD substrate is characterized by having a strain point higher than 630° C., a linear coefficient of thermal expansion over the temperature range of 25°-300° C. of between 32-46×10⁻⁷/° C. The glass is essentially free from alkali metal oxides and has the following composition, expressed in terms of mole percent on the oxide basis:

| | | | |
|---|---|---|---|
| SiO₂ | 64-73 | MgO | 0-5 |
| Al₂O₃ | 9.5-14 | CaO | 1-13 |
| B₂O₃ | 5-17 | SrO | 0-8 |
| TiO₂ | 0-5 | BaO | 0-14 |
| Ta₂O₅ | 0-5. | | |

Examples of typical fining agents for the above composition include Sb₂O₃, CeO₂, SnO₂, Fe₂O₃, and mixtures of these.

Useful glass-ceramic materials for the substrate 12 include, without limitation, silicate-based glass ceramic materials containing silica-based glass phase and a crystal phase. One particularly useful class of useful glass-ceramic materials having the following composition as calculated in weight percent on an oxide basis: 45-70 SiO₂, 14-28 Al₂O₃, 4-13 ZnO, 0-8 MgO, 0-10 TiO₂, 0-10 ZrO₂, 0-15 Cs₂O, 0-5 BaO, ZnO+MgO in combination being greater than or equal to about 8, and TiO₂+ZrO₂ in combination being greater than about 4. Preferably, the glass ceramic substrate exhibits a strain point of 850° C. or above. More preferably, the glass-ceramic material exhibits a shrinkage, when exposed to 900° C. for 6 hours, which is less than 100 ppm. Even more preferably are glass-ceramic materials exhibiting coefficients of thermal expansion between about 22-42×10⁻⁷/° C., over the temperature range of 25-300° C., more preferably between about 30-42×10⁻⁷/° C., and most preferably between about 35-40×10⁻⁷/° C., providing a close thermal expansion match to silicon.

Useful coating materials for the refractory polycrystalline layer 14 include refractory oxide ceramics of the elements such as Al, Mg, Ti, Zr, Y, Ca, Mo, Ce, Hf, Ta, B, V and combinations of these, preferably oxides having low thermal conductivity and/or high electrical permittivity. Some amounts of silica may also be combined with the above materials. In addition, carbides, nitrides, borides and non-oxide refractory materials having low thermal conductivity may also be used. Polycrystalline zirconia has been found to be a particularly useful refractory coating material for the present invention. The refractory coating may be created from a material that is polycrystalline, a material that is polycrystaline and porous, a material that is polycrystalline with crystal parameters near to those of silicon, or most preferably, a material that is polycrystalline with crystal parameters near to those of silicon and porous.

Preferably, when applied to the substrate the refractory coating 14 is porous in nature. The coating can be applied by any suitable coating techniques such as sol-gel, chemical or physical deposition techniques, or by electron, ion, atom or laser beam processes.

Amorphous silicon precursor 16 can be deposited on the refractory layer by any number of techniques. One particularly useful technique is by PECVD which involves silicon deposition from a gas mixture of silane SiH₄ and hydrogen at 300° C. by plasma enhanced chemical vapor deposition. PECVD is usually the preferred deposition technique because large area deposition is possible at a temperature lower than the strain point of glass. The silicon is then crystallized by heat treatment. Examples of heat treatments include, laser annealing techniques, excimer laser annealing, microwave and thermal annealing to name a few.

### EXAMPLES

The invention will be further clarified by the following example.

### Example 1

(a) A zirconia precursor chemical solution was prepared from the hydrolysis and condensation of an organo-zirconium compound, in this case zirconium alkoxide, in ethanol followed by the addition of polyethylene glycol.

(b) A coating of the zirconium solution was deposited by dip coating onto a cleaned 1737 glass substrate.

(c) The deposited coating was heat treated at 550° C. during 1 hour to obtain a porous zirconia film with thickness of about 220 nm and surface roughness of about 0.5 nm. Cubic crystalline phase was measured by XRD. SEM analysis of the cross section revealed a relatively porous structure. The coated substrate was then allowed to cool to room temperature.

(d) Amorphous silicon (silane and helium), was deposited on the zirconia coated 1737 glass at 280° C. to a thickness of about 50 nm.

(e) The sample was heat treated at 450° C. for a duration of about one hour under a nitrogen atmosphere to eliminate residual hydrogen.

(f) The sample was then irradiated with a KrF excimer laser with the fluences in the range of 90 mj/cm²-260 mj/cm².

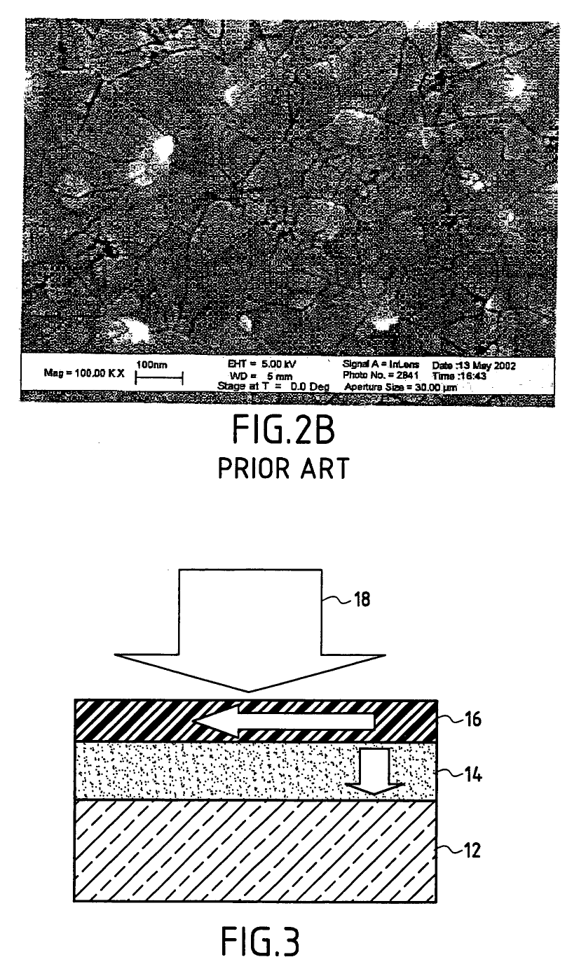

SEM characterization of the irradiated samples shown in FIGS. 2b and 5 confirmed the following:

Decrease in laser fluence for crystallization of silicon with zirconia underlayer Silicon super lateral growth (SLG) observed at lower energies (lower than 140 mJ/cm). Increased silicon grain homogeneity

High material stability to high energy fluences (260 mJ/cm2)

High stability to multi-shot laser irradiation (up to ten shots tested).

Other advantages of the present invention will be apparent to those skilled in the art. For example, with respect to zirconia coated LCDs, we have observed the following advantages:

Thermal conduction of porous zirconia-based layers (20% of porosity) can be reduced up to values close to or lower than silicon oxide. Porosity reduces the impact of zirconia thermal expansion.

Zirconia is a more refractory material than silica and has lower chemical reactivity and higher thermal stability.

Zirconia produces very high crystalline quality silicon due to the fact that its crystalline parameters closely match those of silicon. For example, the unit cell parameters of zirconia (0.5 to 0.53 nm) are close to that of silicon (0.542 nm). And because the lattice match is good, it can induce texturation after laser annealing of silicon layers.

As an additional feature, zirconia has high permittivity and for this reason also provides good electrical insulation. It may also be conceived to use the zirconia layer as an insulating gate oxide.

Finally, zirconia polysilicon coated glass is produced having homogeneous silicon grains.

The present process results in a marked reduction in the cost of excimer laser crystallization process for panel display makers especially on large area substrates without heating the glass substrate. Laser energy is limited in its amount and expense. With a low thermal conductivity coating, a gain of about 30% is made in laser energy density. This is obtained without heating the substrate. Also, thermal insulation of the porous coating protects the glass substrate during laser annealing (pulsed excimer or visible laser, CW laser). Finally, the refractory coating prevents vertical heat conduction and compensates for the waste of laser energy that tends to result when using projection optics (masks). This advantage becomes even more significant in second-generation laser crystallization systems such as in sequential lateral solidification processes where it is expected that use of refractory coatings will directly reduce costs and extend the useful life of the optics.

It will be apparent to those skilled in the art that various modifications and variations can be made to the present invention without departing from the spirit and scope of the invention. Thus it is intended that the present invention cover the modifications and variations of this invention provided they come within the scope of the appended claims and their equivalents.

We claim:

1. A semiconductor device comprising:
a substrate suitable for use in electronic and integrated circuits;
a layer of refractory polycrystalline material formed on at least a portion of the substrate; and
a layer of polycrystalline silicon formed on the refractory layer.

2. The semiconductor device according to claim 1, wherein said device is a thin film transistor (TFT) suitable for applications selected from the group consisting of liquid crystal displays (LCDs) and light emitting diodes (LEDs).

3. The semiconductor device according to claim 1, wherein the substrate is glass, glass-ceramic, ceramic, metal or plastic.

4. The semiconductor device according to claim 1, wherein the refractory material is selected from the group consisting of Al, Mg, Ti, Zr, Y, Ca, Mo, Ce, Hf, Ta, B, V and a combination of these.

5. The semiconductor device according to claim 4, wherein the refractory material is characterized by having low thermal conductivity and high electrical permittivity.

6. The semiconductor device according to claim 4, wherein the refractory material is polycrystalline zirconia.

7. The semiconductor device according to claim 4, wherein the refractory material is an oxide.

8. The semiconductor device according to claim 4, wherein said refractory material is a carbide, nitride or boride.

9. The semiconductor device according to claim 4, wherein said refractory material contains silicon.

10. The semiconductor device according to claim 4, wherein said refractory material is porous.

11. A refractory material layer according to claims 4 to 10, wherein said material is deposited by sol-gel technique or anodic oxidation.

12. The refractory material layer according to claims 4 to 10, wherein said refractory material is deposited by chemical or physical vapor deposition processes.

13. The refractory material layer according to claims 4 to 10, wherein said refractory material is deposited by electron, ion, atom or laser beam processes.

14. The refractory material according to claims 4 to 10, wherein said refractory material has at least one crystal parameter close to that of crystalline silicon

15. A process for making a semiconductor device according to claim 1, in which silicon is deposited by either chemical vapor deposition methods or physical vapor deposition methods.

16. The process according to claim 15, wherein silicon is crystallized using laser annealing techniques

17. The process according to claim 16, wherein silicon is annealed using an excimer laser

18. The process according to claim 16, wherein silicon is crystallized by either microwave annealing, furnace annealing or lamp annealing.

19. The semiconductor device according to claim 1, wherein said device is a PIN diode suitable for applications selected from the group consisting of imaging sensors and photovoltaic devices.
